(19) United States
(12) Patent Application Publication
(10) Pub. No.: US 2008/0272817 A1
(43) Pub. Date: Nov. 6, 2008

(54) Integrated Circuit on a Semiconductor Chip with a Phase Shift Circuit and a Method for Digital Phase Shifting

(76) Inventor: Niels Fricke, Herrenberg (DE)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 12/103,782

(22) Filed: Apr. 16, 2008

(30) Foreign Application Priority Data
May 4, 2007 (DE) 07107485.0

(51) Int. Cl. H03H 11/26

(52) U.S. Cl. 327/277

(57) ABSTRACT

The present invention relates to an integrated circuit on a semiconductor chip with at least one phase shift circuit (56), at least one data input terminal (70) and at least one clock input terminal (38; 68), wherein the phase shift circuit (56) comprises at least two delay chains (10; 20) of the same kind, the delay chain (10; 20) comprises a plurality of inverting elements (12; 22), the phase shift circuit (56) comprises at least one digital control circuit (30), the delay chain (10; 20) is provided to delay a digital signal in a functional mode, the delay chain (10; 20) is provided to operate in a calibration mode, and at least two delay chains (10; 20) are provided to operate alternating between the functional mode and the calibration mode. The present invention relates further to a method for digital phase shifting of a signal (38; 68) within an integrated circuit, wherein the signal (38; 68) is delayed in a delay chain (10; 20) by a predetermined value in an operation mode, while another delay chain (10; 20) of the same kind is calibrated in a calibration mode, and wherein at least two delay chains (10; 20) operate alternating between the functional mode and the calibration mode.

### BACKGROUND OF THE INVENTION

The present invention relates to an integrated circuit on a semiconductor chip with a phase shift circuit and a method for digital phase shifting.

### DESCRIPTION OF THE RELATED ART

The implementation of a double data rate (DDR) SDRAM (Synchronous Dynamic Random Access Memory) interface on an application specific integrated circuit (ASIC) or on a standard integrated circuit requires that the clock signal has to be delayed by a quarter of a clock cycle. This is necessary in order to be able to capture data with this shifted clock signal. Synchronous clock and data signals from an external device arrive at the input terminals of the integrated circuit. The clock edges must be centered into the middle of data edges for reading in the data. In the case of the DDR interfaces the data eye centering requires a precise 90° phase shift of the clock signal.

In the prior art different digital and analog systems and methods for shifting the clock signal are available. These known systems and methods use an actual channel for delaying the clock signal and a reference channel. The prior art systems and methods assume that equal changes in the length of the actual channel and in the length of the reference channel effect the same changes of the delay times.

However, the dimensions of the structures in the actual semiconductor technology are very small. Hence, it is not correct to assume that the same electronic element has the same time delay. Modern transistors have a structure of about three or four atomic layers. Because of the fluctuations in the production process the time delay of two transistors of the same type may differ from 20% to 30%.

The U.S. Pat. No. 6,496,048 B1 describes a system and a method for an accurate adjustment of discrete integrated circuit delay lines. Said system and method comprise drift compensation. A replicate delay line operates continuously in a closed loop mode. Thus, the replicate delay line forms a ring oscillator. A system delay line operates in an open loop mode and creates an absolute time delay. The frequency of the ring oscillator is continuously compared with a reference frequency.

If a deviation occurs, then the lengths of the system delay line as well as the delay line of the ring oscillator are commonly changed. This approach is also based on the assumption, that the same changes of both delay chains effect the same changes of both time delays.

The U.S. Pat. No. 6,593,786 B2 describes a configuration with a plurality of delay chains, provided to compare the delay of a clock tree. This configuration allows compensating the delay of the undivided clock cycle or the half clock cycle. However, it is not possible to compensate a quarter of the clock cycle.

### OBJECT OF THE INVENTION

It is an object of the present invention to provide an integrated circuit on a semiconductor chip with an improved phase shift circuit and an improved method for digital phase shifting.

### SUMMARY OF THE INVENTION

The above object is achieved by a method as laid out in the independent claims. Further advantageous embodiments of the present invention are described in the dependent claims and are taught in the description below.

The core idea of the present invention is a configuration with at least two delay chains of the same kind. In particular, the system comprises two delay chains of the same kind. A first delay chain is set into the functional mode in order to delay a signal, while the second delay chain is being calibrated. Then the second delay chain is set into the functional mode, while the first delay chain is being calibrated.

The calibration process allows a compensation of the changes of the delays. In particular, such changes may result from fluctuations of the temperature and/or the supply voltage. After the calibration process has been finished, then the just calibrated delay chain can be set into the functional mode and the other delay chain can be calibrated.

The phase shift circuit according to the present invention is built only by digital elements. The phase shift circuit includes at least one digital control circuit. The same logic path is used alternating for the functional mode and for the calibration mode. The inventive phase shift circuit allows a variety of phase shifts on the basis of setting the dividers.

The delay chain comprises a plurality of inverting elements. In the calibration mode the delay chain may form a ring oscillator.

The present invention has the advantage that the elements of the delay chain may be exactly calibrated. The individual properties of the delay chains are considered. The present invention does not assume that the delay chains of the same kind have exactly the same properties. The inventive phase shift circuit allows a very high resolution, so that the overall phase error is less than 50 ps.

### BRIEF DESCRIPTION OF THE DRAWINGS

The above as well as additional objectives, features and advantages of the present invention become apparent in the following detailed written description.

The novel and inventive features believed to the characteristics of the invention are set forth in the appended claims. The invention itself and its advantages are best understood by reference to the following detailed description of preferred embodiments in conjunction with the accompanied drawings, wherein:

FIG. 1 illustrates a schematic block diagram of a phase shift circuit according to a preferred embodiment of the present invention,

FIG. 2 illustrates a schematic block diagram of an example of an application for the preferred embodiment of the present invention,

FIG. 3 illustrates a schematic signal diagram with the ideal waveforms of clock and data signals within an application specific integrated circuit,

FIG. 4 illustrates a schematic signal diagram with the waveforms of clock and data signals within an application specific integrated circuit, wherein a skew of data signals and a jitter of clock signals occurs, and

FIG. 5 illustrates a schematic signal diagram with the ideal waveforms of clock and data signals within an application specific integrated circuit, wherein a clock jitter merged into a skew of data signals.

### DETAILED DESCRIPTION OF THE INVENTION

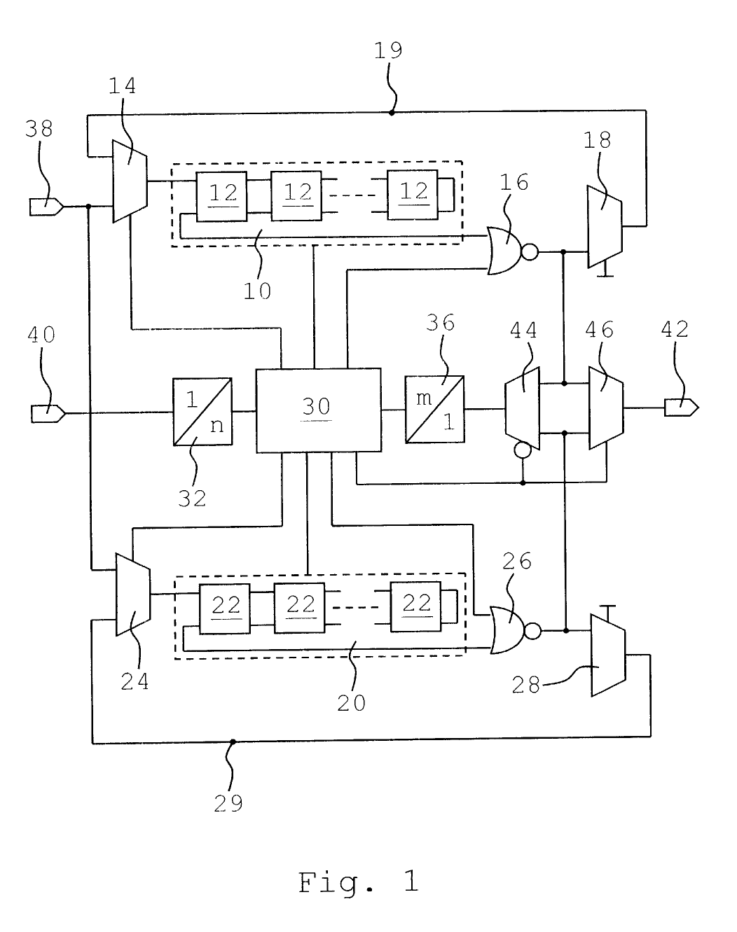

FIG. 1 illustrates a schematic block diagram of a programmable phase shift circuit according to a preferred embodiment of the present invention. The phase shift circuit comprises a first delay chain 10 and a second delay chain 20. The first delay chain 10 and the second delay chain 20 are of the same kind. The delay chains 10 and 20 include a plurality of inverters 12 and 22, respectively. The inverters 12 are connected together, so that an open loop is formed within the delay chain 10. In the same way the inverters 22 are connected together within the delay chain 20. The length of the delay chains 10 and 20 can be controlled.

Additionally, the phase shift circuit comprises a first input multiplexer 14, a second input multiplexer 24, a first NOR gate 16, a second NOR gate 26, a first feedback multiplexer 18 and a second feedback multiplexer 28. The output of the first multiplexer 14 is connected to the input of the first delay chain 10. The output of the second feedback multiplexer 24 is connected to the input of the second delay chain 20. The output of the first delay chain 10 is connected to one input of the first NOR gate 16. In the same way the output of the second delay chain 20 is connected to one input of the second NOR gate 26.

The output of the first NOR gate 16 is connected to the input of the first feedback multiplexer 18. The output of the second NOR gate 26 is connected to the input of the second feedback multiplexer 28. The output of the first feedback multiplexer 18 is connected to one input of the first input multiplexer 14 via a first feedback line 19. In the same way the output of the second feedback multiplexer 28 is connected to one input of the second input multiplexer 24 via a second feedback line 29.

Further, the phase shift circuit comprises a digital control block 30, a first clock divider 32, a second clock divider 36, a first output multiplexer 44 and a second output multiplexer 46. The first output multiplexer 44 has a negative select input, while the second output multiplexer 46 has a positive select input. Both inputs of the first output multiplexer 44 are connected to the inputs of the second output multiplexer 46, respectively.

The digital control block 30 is connected to the programmable delay chains 10 and 20 and to the clock dividers 32 and 36. The digital control block 30 is further connected to the select inputs of the first input multiplexer 14 and the second input multiplexer 24. Additionally, the digital control block 30 is connected to the other input of the first NOR gate 16 and to the other input of the second NOR gate 26. The select inputs of the output multiplexers 44 and 46 are also connected to the digital control block 30.

For external connections, the phase shift circuit comprises an input terminal 38, a clock terminal 40 and an output terminal 42. The input terminal 38 is connected to the other input of the first input multiplexer 14 and to the other input of the second input multiplexer 24. The clock terminal 40 is connected to the input of the first clock divider 32. The output terminal 42 is connected to the output of the second output multiplexer 46. The output of the first output multiplexer 44 is connected to the input of the second clock divider 36. The outputs of the clock dividers 32 and 36 are connected to the digital control block 30.

The first clock divider 32 is provided to divide the reference clock signal from the clock terminal 40. The second clock divider 36 is provided to divide the output signal of the delay chains 10 and 20. The first clock divider 32 and the second clock divider 36 are used for the purpose of calibration.

The digital control block 30 might comprise a phase comparator and, for example, a finite state machine for controlling the multiplexers 14, 24, 44 and 46, the delay chains 10 and 20 and the NOR gates 16 and 26. The digital control block 30 is provided to find a setting for the delay chains 10 and 20 that equalizes the frequency of the two divided clock signals. Alternatively, any other digital circuitry, which is able to perform this task, can also be used.

The clock period PER of the delay chains 10 and 20 is defined as the double of the delay DEL from the input terminal 38 to the output terminal 42. If the frequencies of both divided clock signals from the clock dividers 32 and 36 are the same, then one can calculate:

n*PER(Clk)=m*PER(delay chain)=2*m*DEL(In−Out).

The equation can be transformed to:

DEL(In−Out)=n*PER(Clk)/(2*m).

For example, a setting of n=16 and m=32 creates a delay of a quarter period of the reference clock signal. The advantage of the relative high divider settings is an automatic reduction of calibration errors. For example, said calibration errors may occur due to an inaccurate phase comparator or a jitter of the reference clock signal.

When the first delay chain 10 is set into the functional mode, the second delay chain 20 is calibrated. In this case the functional path of the phase shifted signal extends from the input terminal 38 via the first input multiplexer 14 to the first delay chain 10. The further functional path of the phase shifted signal extends from the first delay chain 10 via the first NOR gate 16 to the second output multiplexer 46 and to the output terminal 42.

When the second delay chain 20 is calibrated, the phase shift circuit effectively forms a ring oscillator. The ring oscillator is started by switching this input of the second NOR gate 26, which is connected to the digital control block 30, from the logical value “one” to the logical value “zero”. The ring oscillator is formed by the second input multiplexer 24, the second delay chain 20, the second NOR gate 26, the second feedback multiplexer 28 and the second feedback line 29.

Once both chains 10 and 20 have been initially calibrated they can be alternating used to shift the signal on the input terminal 38 while the other one is being recalibrated. Any drift due to changes of the temperature and/or the voltage can be cancelled out with this approach.

The resolution of the programmable delay chains 10 and 20 can be assumed to be 10 ps or less. This value can be achieved with a proper logic and physical design in 90 nm or smaller technologies. The mismatches due to on-chip line width variation of the two different multiplexers 44 and 46 can be minimized by placing them in a proper way. An error of less than 25 ps can be assumed to cover this effect.

The frequency comparator in the digital control block 30 is very accurate. The frequencies of the delay chains 10 and 20 are divided before being applied to the frequency comparator. Thus, the impact of any error while comparing the two frequencies is reduced and an error of less than 5 ps can be assumed.

Mismatches of the two clock signals used for calibration leads to an error of less than 10 ps. Adding up the above error values results in a worst case error of about 50 ps for 90 nm or smaller technologies.

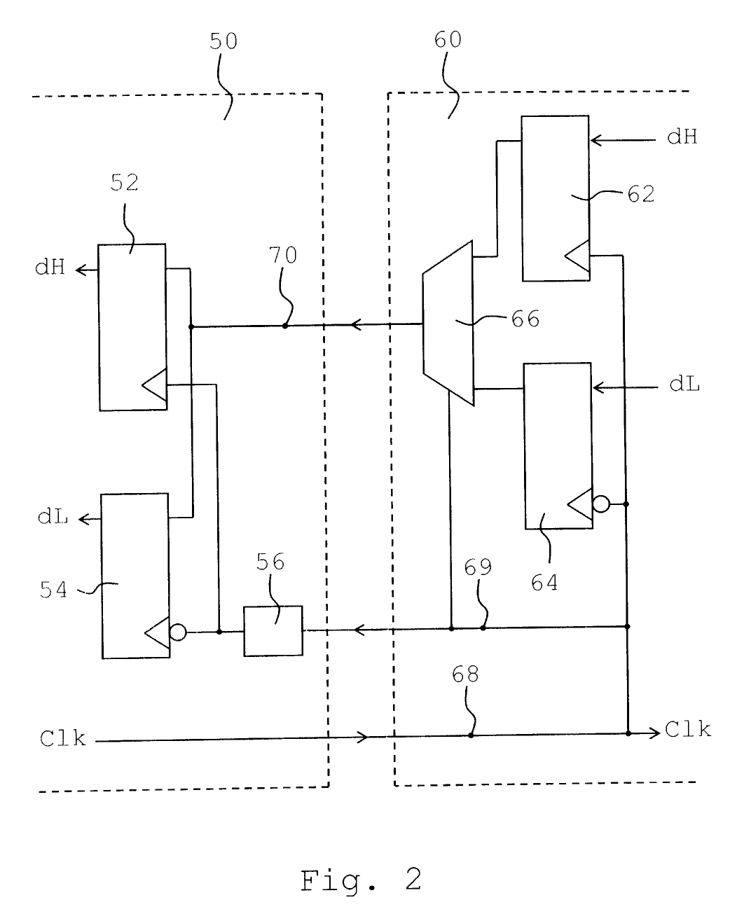

FIG. 2 illustrates a schematic block diagram with an example of an application for the preferred embodiment of the present invention. The application comprises an application specific integrated circuit (ASIC) 50 and an integrated memory circuit 60. The ASIC 50 includes a first flip-flop element 52, a second flip-flop element 54 and a phase shift circuit 56 according to FIG. 1. The first flip-flop element 52 has a positive clock input. The second flip-flop element 54 has a negative clock input.

The integrated memory circuit 60 includes a third flip-flop element 62, a fourth flip-flop element 64 and a multiplexer element 66. The third flip-flop element 62 has a positive clock input. The fourth flip-flop element 64 has a negative clock input. The ASIC 50 and the integrated memory circuit 60 include a first clock signal line 68 and a second clock signal line 69. The signal on the first clock signal line 68 runs from the ASIC 50 to the integrated memory circuit 60. The signal on the second clock signal line 69 runs from the integrated memory circuit 60 to the ASIC 50. The first clock signal line 68 and the second clock signal line 69 are connected together and carry the same signal. However, the signal on the second clock signal line 69 might be delayed against the signal on the first clock signal line 68 because of the wiring length in between the ASIC 50 and the integrated memory circuit 60 and because of the latency due to signal drivers and receivers not shown in FIG. 2. The ASIC 50 and the integrated memory circuit 60 are connected via a data line 70.

The first clock signal line 68 is connected to the clock inputs of the third flip-flop element 62 and the fourth flip-flop element 64. The second clock signal line 69 is connected to the select input of the multiplexer element 66 and to the input of the phase shift circuit 56. The data line 70 connects the output of the multiplexer element 66 to the data inputs of the first flip-flop element 52 and second flip-flop element 54.

The phase shift circuit 56 effects a phase shift with 90° of the original clock signal Clk.

FIG. 3 illustrates a schematic signal diagram with the ideal waveforms of an original clock signal Clk_In on the first clock signal line 68, a shifted clock signal Clk_Shift on the output of the phase shift circuit 56 and a data signal Data_In on the data line 70. The original clock signal Clk_In and the data signal Data_In are synchronous. The shifted clock signal Clk_Shift has a shift of 90° compared with the original clock signal Clk_In.

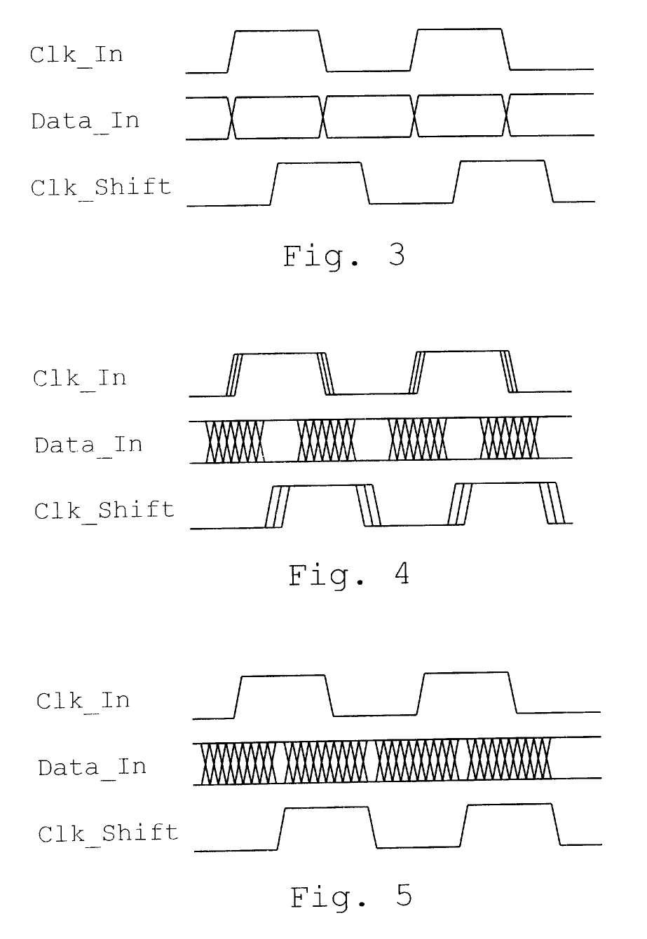

FIG. 4 illustrates a schematic signal diagram with the waveforms of the original clock signal Clk_In, the data signals Data_In and the shifted clock signal Clk_Shift within the ASIC 50 in another situation. Per one clock signal typically a number of data signals Data_In are used. In this situation there is a skew of the data signals Data_In and a jitter of the original clock signal Clk_In. In the shifted clock signal Clk_Shift there occurs also the jitter.

FIG. 5 illustrates a schematic signal diagram with the waveforms of the original clock signal Clk_In, the data signal Data_In and the shifted clock signal Clk_Shift within the ASIC 50 in a further case. In this case the clock jitter merged into the skew of the data signal Data_In.

The present invention can also be embedded in a computer program product which comprises all the features enabling the implementation of the methods described herein. Further, when loaded in a computer system, said computer program product is able to carry out these methods.

Although illustrative embodiments of the present invention have been described herein with reference to the accompanying drawings, it is to be understood that the present invention is not limited to those precise embodiments, and that various other changes and modifications may be affected therein by one skilled in the art without departing from the scope or spirit of the invention. All such changes and modifications are intended to be included within the scope of the invention as defined by the appended claims.

### LIST OF REFERENCE NUMERALS

10 first delay chain
12 inverter of the first delay chain
14 first input multiplexer
16 first NOR gate
18 first feedback multiplexer
19 first feedback line
20 second delay chain
22 inverter of the second delay chain
24 second input multiplexer
26 second NOR gate
28 second feedback multiplexer
29 second feedback line
30 digital control block
32 first clock divider
36 second clock divider
38 input terminal
40 clock terminal
42 output terminal
44 first output multiplexer
46 second output multiplexer
50 application specific integrated circuit (ASIC)
52 first flip-flop element
54 second flip-flop element
56 phase shift circuit
60 integrated memory circuit
62 third flip-flop element
64 fourth flip-flop element
66 multiplexer element
68 first clock signal line
69 second clock signal line
70 data line
m divisor of the second clock divider
n divisor of the first clock divider
dH data high
dL data low
Clk clock signal
PER clock period
DEL delay
Clk_In original clock signal
Clk_Shift shifted clock signal
Data_In data signal

What is claimed is:

1. An integrated circuit on a semiconductor chip with at least one phase shift circuit (56), at least one data input terminal (70) and at least one clock input terminal (38; 68), wherein:
the phase shift circuit (56) comprises at least two delay chains (10; 20) of the same kind;
the delay chain (10; 20) comprises a plurality of inverting elements (12; 22);
the phase shift circuit (56) comprises at least one digital control circuit (30); and
the delay chain (10; 20) is provided to delay a digital signal in a functional mode;
the delay chain (10; 20) is provided to operate in a calibration mode; and
at least two delay chains (10; 20) are provided to operate alternating between the functional mode and the calibration mode.

2. The integrated circuit according to claim 1, wherein the delay chain (10, 20) forms a ring oscillator in the calibration mode.

3. The integrated circuit according to claim 1, wherein a multiplexer (14, 24) is interconnected between the clock input terminal (38; 68) and the delay chain (10; 20).

4. The integrated circuit according claim 1, wherein at least one logic gate (16, 26) is interconnected between the delay chain (10; 20) and an output terminal (42) of the phase shift circuit (56).

5. The integrated circuit according to claim 4, wherein a NOR gate (16, 26) is interconnected between the delay chain (10; 20) and an output terminal (42) of the phase shift circuit (56).

6. The integrated circuit according to claim 1, wherein the phase shift circuit (56) comprises at least one clock divider (32; 36).

7. The integrated circuit according to claim 6, wherein the phase shift circuit (56) comprises two clock dividers (32, 36).

8. The integrated circuit according to claim 6, wherein one clock divider (32) is provided to divide a reference clock signal and the other clock divider (36) is provided to divide the output clock signal of the delay chain (10; 20).

9. The integrated circuit according to claim 1, wherein integrated circuit is an application specified integrated circuit (ASIC) (50).

10. The integrated circuit according to claim 1, wherein the phase shift circuit (56) is provided to delay a clock signal by a predetermined value, in particular by a quarter of the clock period.

11. A method for digital phase shifting of a signal (38; 68) comprising:
delaying the signal (38; 68) in a delay chain (10; 20) by a predetermined value in an operation mode;
calibrating a second delay chain (10; 20) of the same kind in a calibration mode; and
alternately operating the at least two delay chains (10; 20) between the functional mode and the calibration mode.

12. The method according to claim 11, wherein the clock signal (68) is delayed by a predetermined value.

13. The method according to claim 12, wherein the predetermined value is a quarter of the clock period.

14. The method according to claim 11, wherein the method is performed with digital electronic elements.

15. The method according to claim 11, wherein the method is performed on an application specified integrated circuit (ASIC) (50).

16. The method according to claim 11, wherein the system is realized in hardware, software or a combination of hardware and software.

17. A computer program product stored on a computer usable medium, comprising computer readable program means for causing a computer to perform a method comprising:
delaying the signal (38; 68) in a delay chain (10; 20) by a predetermined value in an operation mode;
calibrating a second delay chain (10; 20) of the same kind in a calibration mode; and alternately operating the at least two delay chains (10; 20) between the functional mode and the calibration mode.
